(19) United States
(12) Patent Application Publication
(10) Pub. No.: US 2013/0155795 A1
(43) Pub. Date: Jun. 20, 2013

(54) Methodology for Recovering Failed Bit Cells in an Integrated Circuit Memory

(71) Applicants: Mayank Gupta, Austin, TX (US); John Wuu, Fort Collins, CO (US)

(72) Inventors: Mayank Gupta, Austin, TX (US); John Wuu, Fort Collins, CO (US)

(21) Appl. No.: 13/329,580

(22) Filed: Dec. 19, 2011

(51) Int. Cl. G11C 29/00

(52) U.S. Cl. 365/201

(57) ABSTRACT

A method for recovering failed bit cells in an integrated circuit memory is disclosed. In one embodiment, the method includes stress testing an integrated circuit having a memory, wherein the memory includes a plurality of bit cells. The method further includes holding at least one internal node of the selected one of the plurality of bit cells at a first predetermined state for a period sufficient to cause a shift in a threshold voltage of a transistor in the selected one of the plurality of bit cells.

### 1. FIELD OF THE INVENTION

This invention relates to electronic circuits, and more particularly, to bit cells in a memory implemented on an integrated circuit.

### 2. BACKGROUND

The manufacturing process of integrated circuits typically concludes with one or more production tests. Such production tests may be used to determine that an integrated circuit is functioning correctly. Production tests may also be used to determine various integrated circuit parameters, such as power consumption, which can be used to provide feedback for the manufacturing process. Stress testing may also be performed. For example, one type of stress testing may be used to place an integrated circuit in an environment having an elevated temperature. Such testing may be used to determine whether the integrated circuit can function outside of a normal operating environment. Furthermore, stress testing may be used to accelerate early life failures.

Production testing may include providing various types of test stimuli to the integrated circuit under test. Such stimuli may include providing test vectors to various circuits in the integrated circuit, such as memory test patterns (for embedded memories), logic patterns via scan chains, and so on.

Production testing may be used to screen properly functioning parts from those that are not functioning properly. Passing parts may subsequently be shipped to a customer for installation into a system. Failing parts may be discarded, although some failing parts may be retained for additional failure analysis.

### SUMMARY OF THE DISCLOSURE

A method for recovering failed bit cells in an integrated circuit memory is disclosed in one embodiment. In one embodiment, the method includes stress testing an integrated circuit having a memory, wherein the memory includes a plurality of bit cells. The exemplary method further includes holding at least one internal node of the selected one of the plurality of bit cells at a first predetermined state for a period sufficient to cause a shift in a threshold voltage of a transistor in the selected one of the plurality of bit cells.

In one embodiment, a method includes identifying selected ones of a plurality of bit cells of a memory implemented on an integrated circuit (IC). The selected ones of the plurality of bit cells are identified based on having passed a test of the memory at a first operating point and having failed a test of the memory at a second operating point. The exemplary method further includes performing a dynamic burn-in test of the IC. Performing the dynamic burn-in test includes applying test patterns to the memory while the IC is at a temperature greater than ambient temperature. Performing the dynamic burn-in test further includes holding at least one internal node of a first of the selected ones of the plurality of bit cells at a predetermined state for a period sufficient to cause a change in a threshold voltage of a transistor in the first of the selected ones of the plurality of bit cells.

### BRIEF DESCRIPTION OF THE DRAWINGS

Other aspects of the disclosure will become apparent upon reading the following detailed description and upon reference to the accompanying drawings in which:

FIG. 1 is a block diagram of one embodiment of an integrated circuit having an embedded memory implemented thereon;

FIG. 2 is a block diagram illustrating the arrangement of bit cells in one embodiment of a memory;

FIG. 3 is a schematic diagram of one embodiment of a bit cell used in a memory including an illustration of biasing the bit cell in order to effect a threshold voltage shift;

FIG. 4 is a schematic diagram illustrating one example of the biasing of various nodes of a selected bit cell in order to effect a change in the threshold voltage of a selected transistor therein;

FIG. 5 is a flow diagram illustrating one embodiment of a method for determining which bit cells of a memory are subject to marginal failures at particular operating conditions;

FIG. 6 is a flow diagram illustrating one embodiment of a method for effecting a threshold voltage shift in certain transistors of a marginally failing bit cell in order to recover functionality of that bit cell;

FIGS. 7A and 7B are block diagrams of various embodiments of integrated circuit test systems; and

FIG. 8 is a block diagram of one embodiment of a computer readable medium.

While the invention is susceptible to various modifications and alternative forms, specific embodiments thereof are shown by way of example in the drawings and will herein be described in detail. It should be understood, however, that the drawings and description thereto are not intended to limit the invention to the particular form disclosed, but, on the contrary, the invention is to cover all modifications, equivalents, and alternatives falling within the spirit and scope of the present invention as defined by the appended claims.

### DETAILED DESCRIPTION

### Overview:

The present disclosure is directed to a method for recovering bit cells in a memory of an IC that are subject to marginal failures. Marginally failing bit cells may be defined as bit cells subject to failure at one or more operating points, but pass at one or more additional operating points. The operating points may be defined as including a combination of an operating voltage and an operating frequency (e.g., clock frequency). Operating temperature may also be used to define an operating point in some cases. Other operating points are also possible. A marginally failing bit cell may fail at certain voltage/frequency combinations (e.g., may be incapable of being written to or retaining data), while passing at another voltage/frequency combination. The methodology disclosed herein contemplates causing a shift in a threshold voltage for one or more failing transistors in a marginally failing bit cells such that the bit cells is capable of passing subsequent tests (and thus functioning properly) at each of the operating points at which it previously failed test. As such, the production yield may be increased for IC's having one or more memories implemented with bit cells implemented thereon.

Integrated Circuit with Memory:

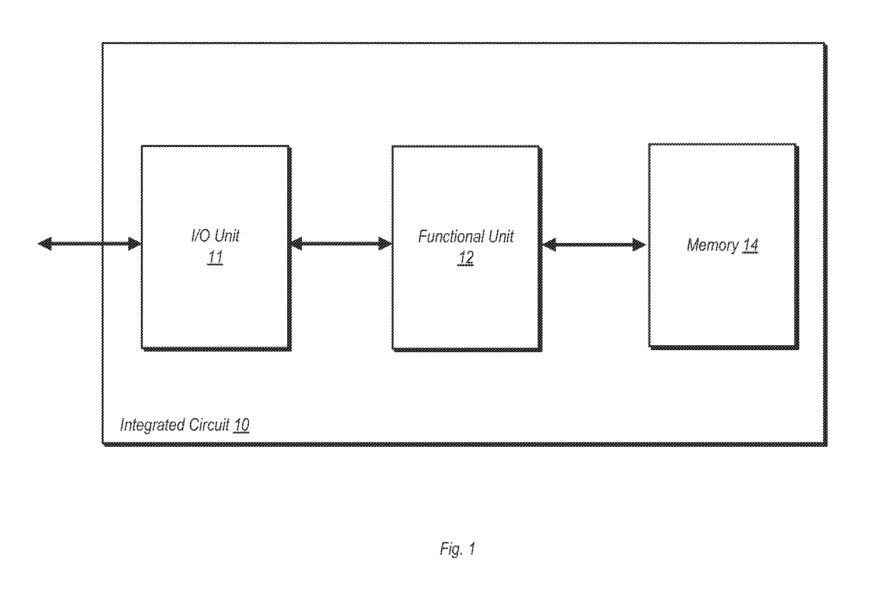

Turning now to FIG. 1, a block diagram of one embodiment of an IC is shown. In the embodiment shown, IC 10 includes an input/output (I/O) unit 11, a functional unit 12, and a memory 14. I/O unit 11 may provide an interface to circuitry external to IC 10, thereby facilitating communications to and from functional unit 12. Functional unit 12, which may not be present in all embodiments of IC 10, may include various types of logic circuitry, and may implement the main functionality of IC 10. In various embodiments, functional unit 12 may include one or more processor cores, graphics processing circuitry, digital signal processing circuitry, or any other type of digital, analog, or mixed-signal circuitry.

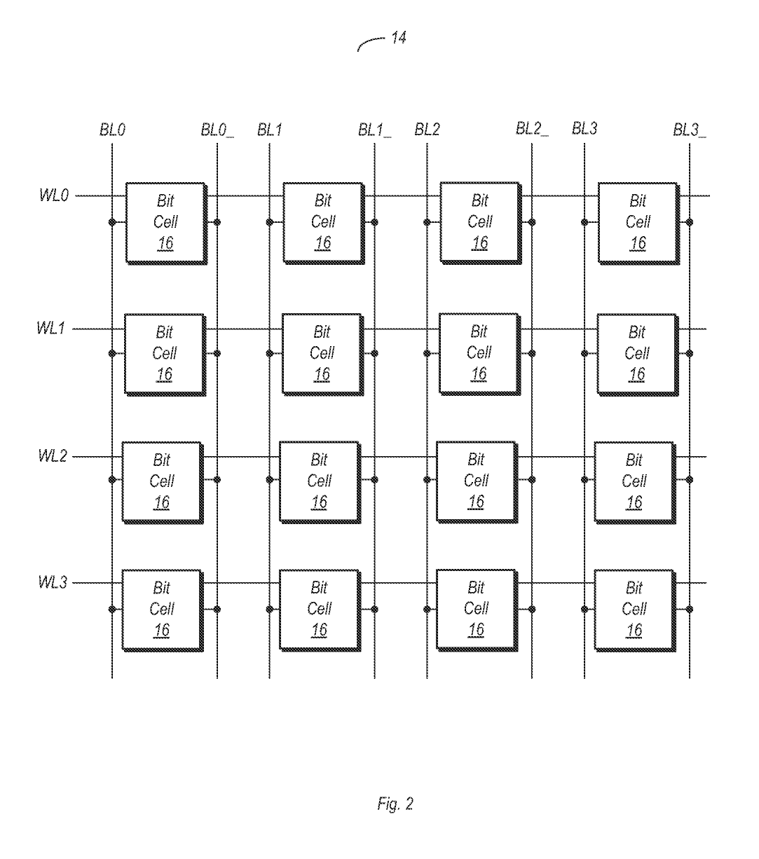

Memory 14 may provide storage for data and/or operands used by functional unit 12 during operation. In one embodiment, memory 14 may be a static random access memory (SRAM), and may include an array of bit cells. FIG. 2 illustrates one embodiment of an arrangement of bit cells in memory 14. Each of the bit cells 16 in the embodiment shown may store one bit of data. Bit cells 16 may be arranged in rows and columns. Each row may correspond to a word, which includes a number of bits. In this particular example, each word includes four bits, although embodiments are possible and contemplated for any suitable number of bits. Each column may correspond to a bit position, e.g., bit 0, bit 1, etc.

Each bit cells 16 in embodiment shown is coupled to a word line and a pair of complementary bit lines. Each word line is coupled to each bit cell 16 in a given row. Each pair of complementary bit lines is coupled to each bit cell 16 of a given column. When a word line is asserted, each of the bit cells 16 in the corresponding row may become transparent to their respectively coupled bit lines. During read operations, a value stored in a bit cell 16 and a complement thereof may be conveyed to the complementary bit lines (e.g., a true value may be conveyed to BL0, a complement of that value may be conveyed to BL0_). Sense amplifiers (not shown here for the sake of simplicity) may receive the values conveyed from bit cells 16 of the selected row and convey corresponding output signals to circuitry external to memory 14. During write operations, drivers (not shown here for the sake of simplicity) may drive the complementary bit lines to logic values received from a source external to memory 14 into the bit cells 16 of the selected row.

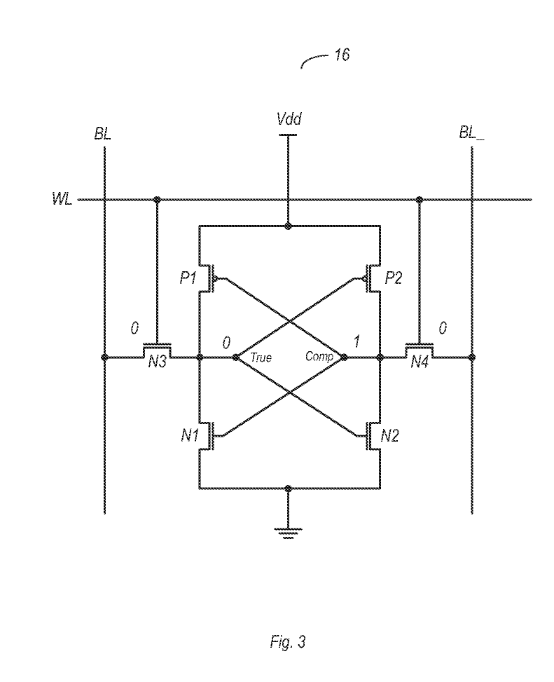

An exemplary bit cell 16 is illustrated in FIG. 3. In the embodiment shown, bit cell 16 includes two cross-coupled inverters arranged to store a bit of data and its complement. A first of these inverters is implemented with transistors P1 and N1, and may drive a logic value on the node labeled ‘True’. A second inverter is implemented with transistors P2 and N2, and may drive a logic value on the complementary node, labeled here as ‘Comp’. The true node in the embodiment shown is coupled to the gate terminals of transistors P2 and N2, and thus serves as an input to the second inverter. The complementary node is coupled to the gate terminals of transistor P1 and N1, and thus serves as an input to the first inverter.

Bit cell 16 may be selected for read or write operations when a corresponding word line (‘WL’) is asserted. When the word line in the embodiment shown is driven to a logic high, transistors N3 and N4 (which act as passgates here) may be activated. When transistors N3 and N4 are active, the true node is coupled to the true bit line (‘BL’) while the complementary node is coupled to the complementary bit line (‘BL_’). During read operations, the values present on the true and complementary nodes may propagate through the passgate transistors to their respectively coupled bit lines. During write operations, logic values driven onto the bit lines may propagate to the true and complementary nodes. During some writes, the logic values driven on the true and complementary bit lines may not be equal to those on the true and complementary nodes, respectively. In such cases, a properly functioning bit cell 16 may cause the true and complementary nodes to ‘flip’, i.e. to change logic states. For example, a logic 1 driven on the true bit line may cause the true node of bit cell 16 to change from a logic 0 to a logic 1 if the bit cell is functioning properly.

During the manufacturing process, IC 10 may undergo one or more production tests near the end of the process in order to ensure it functions properly and per specifications. Such testing may include testing memory 14, and thus bit cells 16. Memory testing may include performing writes to and reads from each of the memory cells 16. The test may be performed at various operating points. Each operating point may include an operating voltage and may further include an operating frequency. An operating voltage may be defined as the supply voltage provided to each of memory cells 16 (e.g., the voltage on Vdd as shown in FIG. 3). With respect to memory 14 and bit cells 16, an operating frequency may be defined as the frequency at which the cells may be written to and read from, and more generally, how fast consecutive operations may be performed in the memory. The operating frequency may correspond to a frequency of a clock signal used in the IC upon which memory 14 is implemented.

In some cases, certain instances of bit cells 16 may fail testing at all operating points. Such bit cells may be defective for reading (e.g., unable to hold the properly written state) or writing (e.g., unable to write a given logic value to the bit cell). In some embodiments of an IC, bit cells that fail for all operating points may be replaced by bit cells in a redundant array that is provided for this very purpose. In embodiments of an IC lacking a redundant array, the IC may be considered defective and thus discarded.

Marginal failures are also possible for some bit cells 16. For the purposes of this disclosure, a marginal failure may be defined as a failure occurring during the test of a bit cells at a certain operating point, whereas such bit cells are capable of properly functioning at other operating points. For example, a given instance of a bit cell 16 may be capable of properly functioning (and thus passing a test) at a nominal voltage and operating frequency, whereas the same bit cell may be incapable of properly functioning at an operating point having a lower-than-nominal voltage and/or higher-than-nominal frequency. In such cases, the functionality of such bit cells 16 may be replaced by redundant arrays, or the corresponding IC may be discarded. The present disclosure, however, contemplates a methodology in which the full functionality of such bit cells 16 may be recovered. Full functionality may be defined as the ability of a bit cell to function at all intended operating points, e.g., at all specified operating voltages and operating frequencies for the IC upon which the corresponding memory is implemented. In the present disclosure, the full functionality may be recovered by performing stress testing while writing certain patterns to a marginally failing bit cell 16. This may induce a threshold voltage shift of a transistor in the marginally failing bit cell 16, which may restore it to full functionality.

In the embodiment shown of a bit cell 16 in FIG. 3, logic values of 0 are shown on the gate terminals of transistors N3 and N4, thereby isolating bit cell 16 from adjacent cells. Furthermore, a logic 0 is present on the true node, while a logic 1 is present on the complementary node. In this example, this configuration may be used to induce a shift of a threshold voltage in transistor P2. After determining that bit cell 16 of FIG. 3 is marginally failing, the IC in which it is implemented may be subject to a stress test, and more particularly, a burn-in test. The burn-in test may include testing the IC at a temperature that is significantly above ambient temperature (e.g., 70° C. with a room temperature of 21° C.). The burn-in test may be a dynamic burn-in test, which may be defined as a burn-in test in which test patterns are applied to the memory while operating at the elevated temperature. In this particular case, while other bit cells 16 may be toggled (i.e., have alternating values of logic 0 and logic 1 written thereto), bit cell 16 in FIG. 3 may have a logic 0 held on the true node for a period of sufficient length to induce a shift of the threshold voltage of transistor P2. If it is desired to shift the threshold voltage of transistor P1, a similar procedure may be performed with a logic 0 held on the complementary node.

The methodology described herein may take advantage of the phenomena known as negative bias temperature instability (NBTI). Normally, NBTI is an undesirable occurrence, although it may occur over time with transistors implemented in IC's (particularly PMOS transistors). NBTI may be described as a threshold voltage shift of the transistor that occurs over time. Causes of the threshold voltage shift may include temperature, voltage stress on the gate oxide of the transistor, and an amount of time the stressing voltage (i.e. the bias applied to the gate terminal of the transistor) is applied to the gate. In the methodology described herein, a stressing voltage may be applied to the gate terminal of a transistor for which a threshold voltage is desired. The stressing voltage may be applied during the dynamic burn-in test, and may be held on the gate for a time sufficient to cause the threshold voltage to shift.

In the example of FIG. 3, the application of a logic 0 to the gate terminal of transistor P2 may cause an increase in the threshold voltage of transistor P2 over time, due to NBTI (e.g., the gate voltage may become more negative relative to the source voltage). For a PMOS transistor, activation may occur when the magnitude of the gate-source voltage is greater than the magnitude of the threshold voltage. This may be expressed mathematically as |V_{gs}|>|Vₜ|, or V_{gs}<Vₜ, since the threshold voltage is negative with respect to the source voltage. Thus, for larger magnitudes of the threshold voltage, the more negative the gate voltage is driven with respect to the source voltage when turning on the device. While this situation may provide a stronger drain current when the transistor is active, it may cause problems when reading or writing to bit cell 16. For example, if the voltage of a logic 0 is too high when received from the true bit line via transistor N3, transistor P2 may fail to activate. If transistor P2 fails to activate during a write in which bit cell 16 is to be flipped, the complementary node may not be changed from a logic 0 to a logic 1. This may also affect the state of the true node once passgate transistors N3 and N4 are deactivated. One cause of such a marginal failure may be a less than optimal balance between transistors of bit cell 16. This failure mechanism may in some cases be a marginal failure mechanism, occurring at some operating points but not others. For example, at one operating voltage and/or frequency, a logic 0 conveyed from the true bit line may be able to cause the activation of P2 (based on its threshold voltage) in order to flip the complementary node of bit cell 16 from a previously stored logic 0 to a logic 1, thereby resulting in a successful write. However, at another operating voltage and/or frequency (e.g., a lower voltage), the threshold voltage of P2 may be such that a logic 0 conveyed from the true bit line across passgate transistor N3 may be insufficient to cause P2 to activate and thus flip the complementary node from a logic 0 to a logic 1. Such a case in which writes may be successfully performed on a bit cell at one operating point but not at another may be defined as a marginal failure.

To overcome this failure, the logic 0 on the true node, and thus on the gate terminal of P2, may be held for a sufficient time while operating at the elevated temperature of the burn-in test to cause the threshold voltage to increase. An increase in the threshold voltage of P2 may in turn result in a corresponding decrease in the magnitude of the threshold voltage. After the threshold voltage shift is in effect, transistor P2 may be activated for smaller values of |V_{gs}|. This in turn may make transistor P2 easier to activate during writes, while reducing its likelihood of an unintentional deactivation during reads or due to possible leakage through transistor N3. Furthermore, the marginal failure may be eliminated, and may thus allow bit cell 16 to properly function at all specified operating points of the IC in which it is implemented. It is noted that the above discussion as applied to P2 may also be similarly applied to transistor P1.

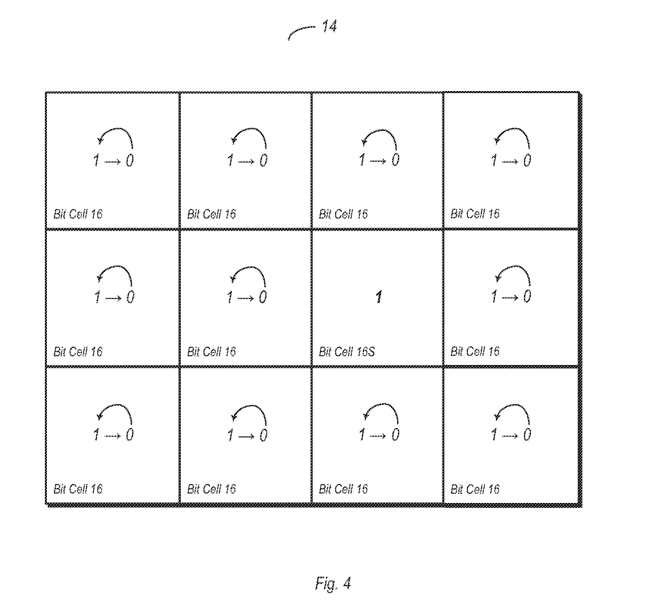

While causing a threshold voltage shift in a selected bit cell 16, it may be desirable that transistors in other bit cells 16 not be subject to the same NBTI effects in the selected bit cell. Accordingly, the other bit cells may be electrically and functionally isolated from the selected bit cell during the performing of the threshold voltage shift. During a portion of this time, selected bit cell 16S may be isolated from the non-selected bit cells 16 by holding the word line in a de-asserted state, and thus holding passgate transistors N3 and N4 inactive. Furthermore, as shown in FIG. 4, non-selected bit cells 16, including those adjacent to the selected bit cell 16S, may have there respective states toggled while the state of bit cell 16S is held steady for an amount of time sufficient to cause the desired shift in a threshold voltage of a transistor therein. In the example shown in FIG. 4, a number of bit cells 16 and a selected bit cell 16S of memory 14 are shown. The logic values shown in this example may represent a logic value written to the respective true node of each bit cell 16 and 16S. The logical complement of these values may be written to the respective complementary node of each bit cell 16 and 16S. For the non-selected bit cells 16, the logical values written therein may be toggled at least once during the dynamic burn-in test, and may be toggled continuously in some cases (e.g., to provide enough time to cause the desired threshold voltage shift). The amount of time that nodes of the non-selected cells are held at a logic 0 and logic 1 states may be substantially equal during the dynamic burn-in test. Changing the state of the non-selected bit cells 16 during the dynamic burn-in testing may prevent unwanted threshold voltage shifts of transistors therein. In contrast, the selected bit cell 16S may be initially written to a certain state (logic 1 on the true node in this example) and held in that state for the amount of time necessary to induce the desired threshold shift. During the portions in which the non-selected bit cells 16 are written to new states, the selected bit cell 16S may be rewritten as a logic 1 in order to cause it to hold its state.

The process described above may be performed for a number of different bit cells 16 that may exhibit marginal failures. In some cases, two or more bit cells 16 may undergo this process concurrently, particularly if the time sufficient to induce the desired threshold voltage shift for a transistor in each is substantially the same (which may be indicated by such bit cells 16 exhibiting similar failure characteristics). In other cases, marginally failing ones of bit cells 16 may undergo the above-described process sequentially, particularly if the times to induce the desired threshold voltage shifts are substantially different from one another.

It should be noted, that, while memory 14 is shown as implemented on IC 10 along with functional unit 12, embodiment of an IC that are dedicated to implementing a memory are possible and contemplated, and may thus fall within the scope of memories discussed in this disclosure.

### Method Flow Diagrams:

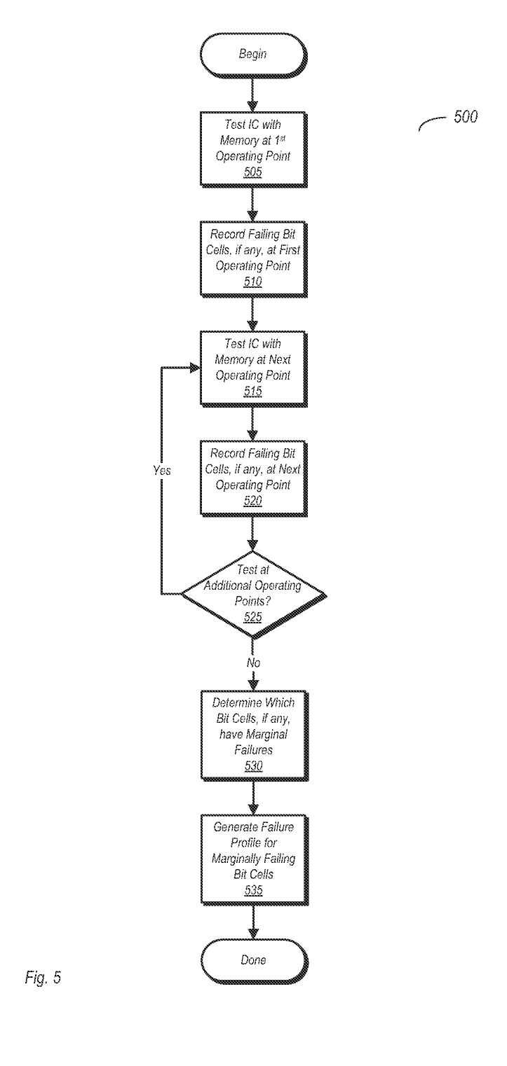

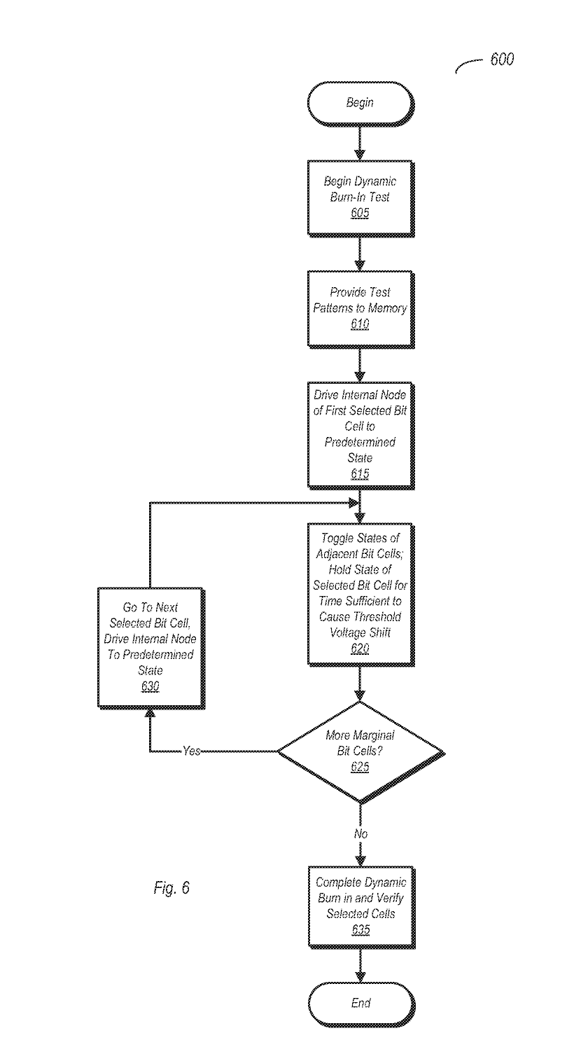

Turning now to FIG. 5, a flow diagram of one embodiment of a method for performing a production test of a memory implemented on an IC is shown. For the methodology described herein, production testing may be used to determine failure information for any bit cells of an IC that are not functioning as intended. From the failure information gathered, a failure profile may be generated. If a memory includes marginally failing bit cells but no hard failures (i.e. bit cells that fail under all operating conditions tested), the failure provide may be used to generate test patterns for a subsequent dynamic burn-in test. During the dynamic burn-in test (which will be discussed further in reference to FIG. 6), an attempt may be made to recover the full functionality of the marginally failing bit cells.

Method 500 begins with the testing of an IC having a memory implemented thereon at a first operating point (block 505). In one embodiment, the testing may be performed by an IC test system, embodiments of which will be discussed in further detail below. The test may include a test directed to the memory in which multiple writes and reads are performed to ensure that each bit cell of the memory is capable of having information written thereto and can further retain written information for subsequent reads. As noted above, an operating point may be defined by at least an operating voltage (e.g., a voltage supplied to the memory) and/or and operating frequency (e.g., a frequency at which operations may be performed on the bit cells). During testing at the first operating point, information may be recorded regarding any bit cells that fail (block 510). The information may indicate whether attempts to write to a given bit cell failed, or whether information previously verified as written to a bit cell was unable to be read at some point subsequent to it being written.

Upon conclusion of testing at the first operating point, a subsequent test may be performed at a next operating point (block 515). Testing at the next operating point may be performed at either a different operating voltage, a different operating frequency, or both relative to testing at the first (or previous) operating point. Any bit cell failures occur during testing at the next operating point may be recorded, along with any pertinent information relating to such failures (block 520). It is noted that some marginally failing bit cells may function properly at the first operating point but fail at the next operating point. Similarly, some marginally failing bit cells may fail to function properly at the first operating point, but may function properly at the next operating point at which testing is conducted. In general, testing may include testing at one or more nominally passing operating points to one or more extreme operating regions in order to increase the chances of exposing marginally failing bit cells.

If testing is to be conducted at additional operating points (block 525, yes), then blocks 515 and 520 may be repeated. In some embodiments, blocks 515 and 520 may be repeated for a number of iterations to ensure that the memory is tested at as many operating points as possible or feasible. This may ensure that the memory is exercised across a wide variety of specified operating points.

If testing is not to be conducted at any additional operating points (block 525, no), a determination may then be made as to which failing bit cells (if any), are marginally failing bit cells (block 530). Bit cells that fail to function properly at some operating points but do function properly at others may be considered marginal failures. Information gathered from testing may be used to indicate whether marginally failing bit cells are read limited (i.e., cannot be properly read at all operating points tested) or write limited (i.e., cannot be properly written to at all operating points tested).

Failing bit cells that fail at all operating points tested may be considered hard failures. In some cases, bit cells that are hard failures may be replaced by bit cells of a redundant array implemented on board the same IC for this purpose. However, if the number of hard failures exceeds the replacement capacity provided by the redundant array, or the IC lacks a redundant array, the IC may be rendered unusable. In such cases, the IC may either be discarded or kept for subsequent failure analysis that may be used in attempts to improve the IC manufacturing process.

It is noted that in some cases, no bit cells will fail to function properly at any operating point at which testing is conducted. Accordingly, in such cases, blocks 530 and 535 are rendered moot.

Following the determination of which bit cells have failed, a failure profile may be generated (block 535). The failure profile may include information regarding the marginally failing bit cells. As noted above, the information gathered from marginally failing bit cells may indicate at which operating points these bit cells failed, whether the bit cells are read limited, write limited, or both, and so on. Additional information (e.g., parametric information such as voltage and current information) may also be included in the failure profile.

The failure profile for marginally failing bit cells may be used to determine actions which may be used to recover their functionality. More particularly, the failure profile information may be used to determine which transistor(s) of a bit cell may be contributing to the marginal failures. From this information, corrective actions to recover the functionality of marginally failing bit cells may be determined. The corrective action may include shifting a voltage threshold of a transistor (or transistors) causing the marginal failure. The actions necessary to induce such voltage threshold shifts may also be determined based on the failure profile information for marginally failing bit cells.

FIG. 6 is a flow diagram illustrating one embodiment of a method for conducting a dynamic burn-in test in which voltage threshold shifts may be induced into a transistor or transistors of a marginally failing bit cell. A burn-in may be a procedure in which the temperature of a device may be elevated to a temperature that is significantly above ambient temperature. The burn-in may be conducted in a burn-in chamber (sometimes referred to as an ‘oven’) in which the device or devices subject to the burn-in in are heated to a high temperature. For example, devices in a room that has an ambient temperature of 21° C. may be heated inside the burn-in chamber to a temperature of 70° C.

A dynamic burn-in test may be a burn-in of an IC in which the IC is tested while at the elevated temperature. The dynamic burn-in test may include applying various types of test stimulus to a device under test (e.g., an IC) and receiving results from the applied test stimulus to determine whether proper functionality occurs at the elevated burn-in temperature. When testing a memory during a dynamic burn-in test, various reads and writes (similar to those conducted during the production test discussed above) may be performed to determine if the bit cells function properly. In addition, for the method to be discussed in reference to FIG. 6, marginally failing bit cells may be intentionally placed in a state in which NTBI occurs and thus causes a shift in a threshold voltage of a selected transistor (or transistors) of the bit cell.

Method 600 begins with the initiation of a dynamic burn-in test (block 605) as described above. The dynamic burn-in test may be conducted on an IC that includes a memory having a number of bit cells. During the dynamic burn-in test, various test patterns may be applied to the memory (block 610). In applying the test patterns, a node of a first selected bit cell may be driven to a predetermined state (block 615). The first selected bit cell may be one in which was designated as a marginal failure. The internal node may be driven in a manner intended to create an NBTI-induced threshold voltage shift of a particular transistor in the first selected bit cell. The internal node may be held in the driven state for a time that is sufficient to cause the threshold voltage shift of the targeted transistor, while other bit cells, including those adjacent to the first selected bit cell, may have their states toggled (block 620). The bit cells that are toggled at this time may have their states written in an alternating sequence of logic 1's and logic 0's. Toggling the states of non-selected bit cells may ensure that unintended threshold voltage shifts are not induced in their respective transistors. After a time sufficient to cause the threshold voltage of the targeted transistor has elapsed, the state of the first selected bit cell may be toggled.

If there are additional bit cells that are indicated as marginal failures, (block 625, yes), then an internal node of the next selected bit cell may be driven to a predetermined state (block 630). The predetermined state may be held for a time sufficient to cause a threshold voltage shift in a targeted transistor of the next selected bit cell, while the states of other bit cells are toggled (block 620). Blocks 630 and 620 may be repeated for any number of iterations corresponding to bit cells that are classified as marginal failures. In some cases, the process may be repeated for a marginally failing bit cell in which more than one transistor thereof is targeted for a threshold voltage shift. Furthermore, while it is noted that the method embodiment illustrated by FIG. 6 is directed to performing the threshold shift procedure for marginally failing bit cells in sequential manner, in some cases two or more bit cells may undergo this procedure concurrently. In particular, when the time required to induce a desired threshold voltage shift for a corresponding transistor in two or more different bit cells is substantially the same, the procedure may be performed on these cells concurrently.

If no additional bit cells are to undergo the procedure of shifting a threshold voltage of a corresponding transistor (block 625, no), then the dynamic burn-in test may be completed (block 635). Furthermore, verification may be performed to determine if the selected cells function as intended after undergoing the procedure described above. In one embodiment, the verification step may be performed during a subsequent production test similar to that discussed above with respect to FIG. 5. The production test may include testing at various operating points to ensure that all bit cells are properly functioning, including those that had one or more transistors subject to a threshold voltage shift. In another embodiment, a test similar to the production test may be conducted on the same test system upon which the dynamic burn-in test was conducted. Such testing may be conducted in some embodiments after the IC under test has been allowed to cool back down to a temperature that is at or near ambient temperature.

### IC Test Systems:

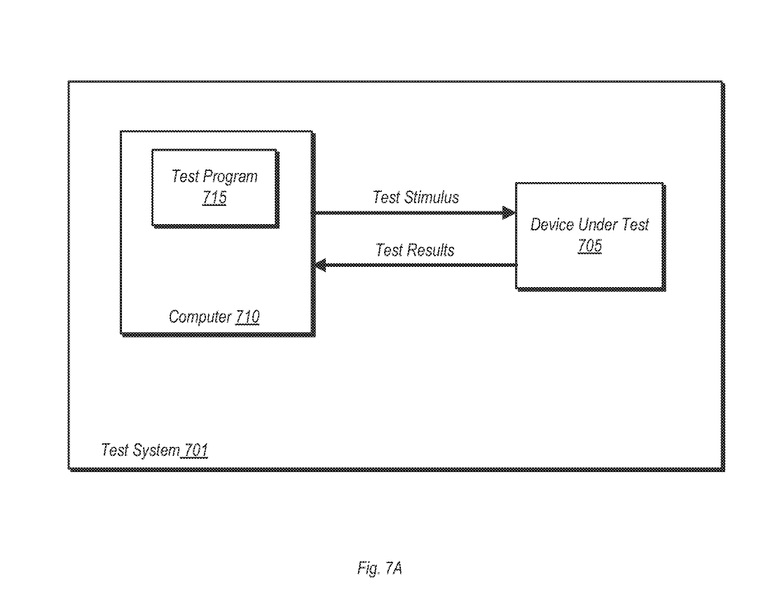

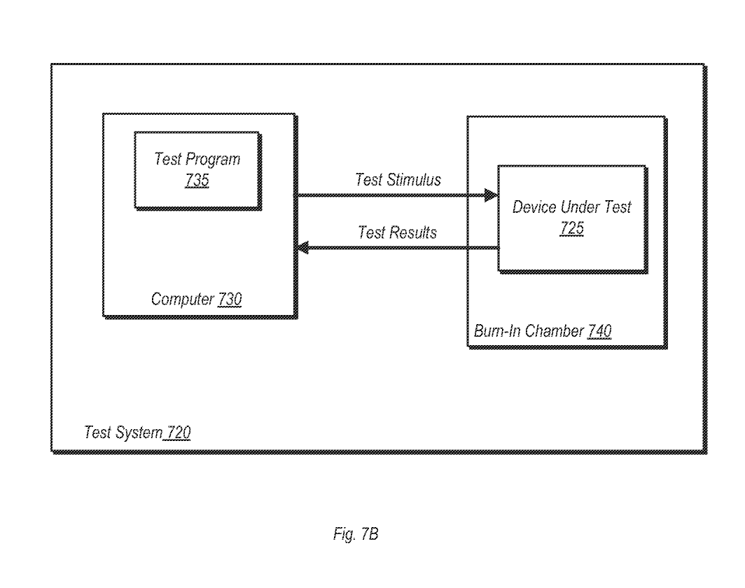

FIGS. 7A and 7B illustrate embodiments of test systems that may perform the tests described above. FIG. 7A is directed to a production test system, while FIG. 7B is directed to a test system configured to perform a dynamic burn-in test. The production test system may be used to test instances of an IC that are to be shipped to a customer. The dynamic burn-in test system may be used to perform a dynamic burn-in test on instances of an IC intended for shipping to a customer, and may also be used to perform the process described above in which a threshold voltage shift is induced in certain transistors of a bit cell determined to be marginally failing during production test.

Test system 701 illustrated in FIG. 7A includes a computer system 710 that is configured to execute a test program 715. Execution of the test program by computer system 710 may include providing test stimulus to a device under test 705 (e.g., an IC). Additionally, execution of the test program may also include receiving and storing test results received from device under test 705 responsive to the applied test stimulus. The test stimulus may include test patterns that are applied to a memory on device under test 705, including various cycles of writing to the memory and reading from the memory. Additional test stimulus may be applied to other functional units of device under test 705 to verify intended functionality thereof.

In addition to providing test stimulus and receiving test results, execution of test program 715 by computer 710 may also include generating various types of databases based on the received test results. In one embodiment, a database may include a failure profile generated during the testing of a memory on the device under test 705. The failure profile may indicate which, if any of the bit cells of the memory are subject to hard failures, as well as which, if any bit cells are subject to marginal failures. For those bit cells that are subject to marginal failures, the database may include information regarding the operating points at which the bit cells passed test (e.g., functioned as intended) and the operating points at which the bit cells failed test (e.g., did not function as intended). Additional information for each of the marginally failing bit cells may indicate whether that bit cells was read limited, write limited, or both. Parametric information (e.g., voltages and currents) may also be indicated in some cases.

From the failure profile, a plan to recover the marginally failing bit cells may be generated. The plan may include generation of various test patterns to be applied to the bit cells of the memory during a dynamic burn-in test. Such test patterns may include instructions to drive selected nodes of marginally failing bit cells to a predetermined state for a time sufficient to induce a desired threshold voltage shift in a targeted transistor. Changing the threshold voltage of one or more transistors in a marginally failing bit cell may in turn change the operation of that cell such that it subsequently functions properly at all intended operating points.

Test system 720 of FIG. 7B is configured for performing dynamic burn-in testing. In addition to including a computer system 730 configured to execute a test program 735, test system 720 also includes a burn-in chamber 740 in which device under test 725 is placed during testing. Burn-in chamber 740 may isolate the device under test 725 from ambient conditions in the room or space where the dynamic burn-in test is conducted. Furthermore, burn-in chamber 740 may be configured to elevate the temperature within itself to a level that is above the ambient temperature. In some embodiments, the temperature and its rate of elevation may be controlled by computer 730 in accordance with instructions in test program 735.

Test program 735 may also include a failure profile including information regarding bit cells of a memory indicated as marginally failing during a previously performed production test. In addition, test program 735 may also include instructions that, when executed by computer system 730, cause test patterns to be applied to a memory in device under test 725 in such a manner as to induce threshold voltage shifts in targeted transistors of the marginally failing bit cells. As discussed above, an internal node of a bit cell indicated as marginally failing may be driven to a predetermined state for a time that is sufficient to induce a desired threshold voltage shift in the targeted transistor.

In various embodiments, test system 700 may be configured to perform the method discussed above in reference to FIG. 5. Similarly, various embodiment of test system 720 may be configured to perform the method discussed above in reference to FIG. 6. It is noted however that these test systems may also be configured to perform additional types of testing not explicitly discussed herein.

### Computer Readable Medium:

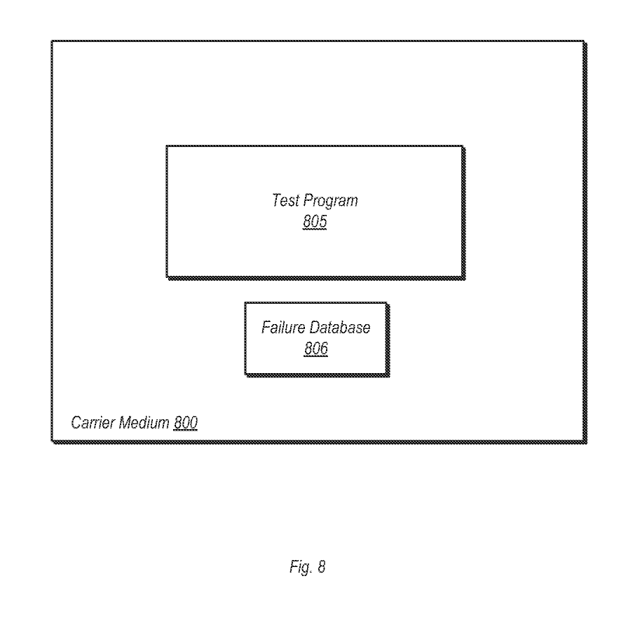

Turning next to FIG. 8, a block diagram of a computer accessible storage medium 800 including a test program 805 for testing an IC including a memory having a number of bit cells. Computer accessible storage medium also includes a failure database 806 in the embodiment shown, which may include information about bit cells of one or more memories that have failed a test and conditions under which those failures occurred.

Generally speaking, a computer accessible storage medium 800 may include any non-transitory storage media accessible by a computer during use to provide instructions and/or data to the computer. For example, a computer accessible storage medium 800 may include storage media such as magnetic or optical media, e.g., disk (fixed or removable), tape, CD-ROM, or DVD-ROM, CD-R, CD-RW, DVD-R, DVD-RW, or Blu-Ray. Storage media may further include volatile or non-volatile memory media such as RAM (e.g. synchronous dynamic RAM (SDRAM), double data rate (DDR, DDR2, DDR3, etc.) SDRAM, low-power DDR (LPDDR2, etc.) SDRAM, Rambus DRAM (RDRAM), static RAM (SRAM), etc.), ROM, Flash memory, non-volatile memory (e.g. Flash memory) accessible via a peripheral interface such as the Universal Serial Bus (USB) interface, etc. Storage media may include microelectromechanical systems (MEMS), as well as storage media accessible via a communication medium such as a network and/or a wireless link.

Test program 805 may include data and instructions that, when executed on an IC test system, perform a test of an IC. The test program may be directed to performing a production test as discussed above with reference to FIG. 5, and may be performed on an embodiment of a test system such as that discussed above in reference to FIG. 7A. Execution of the instructions may also cause the generation of failure database 806 based on test results received from the IC under test. The test results may be received responsive to test stimulus generated during the execution of certain instructions of test program 805 by the corresponding test system.

In another embodiment, test program 805 may include data and instructions that, when executed on a burn-in tester, perform a dynamic burn-in test of an IC. The test program may be directed to performing a dynamic burn-in test as discussed above in reference to FIG. 6, and may be performed on an embodiment of a test system such as that discussed above in reference to FIG. 7B. In this embodiment, failure database 806 may include information generated during a previously performed production test. The failure information may include a failure profile for one or more bit cells of a memory that were indicated as marginal failures during the production test. Test program 805 may include instructions that, when executed by a dynamic burn-in test system, access the failure profile for the marginally failing bit cells and apply various states to these bit cells in order to induce threshold voltage shifts in targeted transistors thereof. By inducing the threshold voltage shifts in certain transistors of marginally failing bit cells, full functionality of these bit cells may be recovered. By recovering the full functionality of bit cells initially classified as marginal failures, manufacturing yields for IC's containing the corresponding memories may be improved. This may save the cost of IC's that would otherwise be designated as unsuitable for shipping to a customer.

Alternatively, computer accessible storage medium 800 may include any non-transitory storage media accessible by a computer during use to provide instructions and/or data to the computer that is used to configure a manufacturing process to manufacture an IC such as IC 10 (FIG. 1). For example, computer accessible storage medium may include hardware description language code, register transfer language (RTL) code or Graphic Data System (GDS) II code, that can be used, directly or indirectly, to configure an integrated circuit (IC) fabrication (e.g., manufacturing) facility using, for example, mask works created based on the code stored in computer accessible storage medium 800. The IC so manufactured will then embody aspects of the present invention.

While the present invention has been described with reference to particular embodiments, it will be understood that the embodiments are illustrative and that the invention scope is not so limited. Any variations, modifications, additions, and improvements to the embodiments described are possible. These variations, modifications, additions, and improvements may fall within the scope of the inventions as detailed within the following claims.

What is claimed is:

1. A method comprising:
stress testing an integrated circuit having a memory, wherein the memory includes a plurality of bit cells; and
holding at least one internal node of the selected one of the plurality of bit cells at a first predetermined state for a period sufficient to cause a shift in a threshold voltage of a transistor in the selected one of the plurality of bit cells.

2. The method as recited in claim 1, further comprising:
holding at least one internal node of one or more additional ones of the plurality of bit cells at corresponding ones of a one or more predetermined states for corresponding periods sufficient to cause threshold voltage shifts for at a transistor of each of the one or more additional ones of the plurality of bit cells.

3. The method as recited in claim 2, wherein the selected one of the plurality of bit cells and the one or more additional ones of the plurality of bit cells are determined based on each failing during a production test for at least a first operating point.

4. The method as recited in claim 3, wherein each of the selected one of the plurality of bit cells and the one or more additional ones of the plurality of bit cells is determined based on passing a production test for at least a second operating point.

5. The method as recited in claim 4, further comprising determining, for each of the selected one of the plurality of bit cells and the one or more additional ones of the plurality of bit cells, whether that bit cells is read limited or write limited.

6. The method as recited in claim 4, wherein first operating point includes a first operating voltage and a first operating frequency, and wherein the second operating point includes a second operating voltage and a second operating frequency.

7. The method as recited in claim 1, further comprising electrically isolating the selected one of the plurality of bit cells from one or more adjacent ones of the plurality of bit cells.

8. The method as recited in claim 1, wherein the transistor is a p-channel metal oxide semiconductor (PMOS) transistor.

9. The method as recited in claim 8, wherein said holding causes the threshold voltage of the PMOS transistor to increase.

10. The method as recited in claim 1, further comprising holding at least one additional internal node of the selected one of the plurality of bit cells at another predetermined state for a period sufficient to cause a shift in a threshold voltage of another transistor in the selected one of the plurality of bit cells.

11. The method as recited in claim 1, wherein said stress testing comprises testing the integrated circuit at a temperature greater than an ambient temperature.

12. A computer readable medium storing instructions that, when executed on an integrated circuit (IC) test system, cause the IC test system to perform a test of an IC including a memory having a plurality of bit cells, wherein testing the IC comprises:
holding at least one internal node of the selected one of the plurality of bit cells at a first predetermined state for a period sufficient to cause a shift in a threshold voltage of a transistor in the selected one of the plurality of bit cells.

13. The computer readable medium as recited in claim 12, wherein the IC test system is configured to perform a stress test of the IC, wherein the stress test comprises testing the IC at a temperature greater than ambient temperature.

14. The computer readable medium as recited in claim 12, wherein holding the at least one internal node at the first predetermined state comprises holding a gate of the transistor at a specified logic level.

15. The computer readable medium as recited in claim 12, wherein testing the IC further comprises:
holding at least one internal node of one or more additional ones of the plurality of bit cells at corresponding ones of a one or more predetermined states for corresponding periods sufficient to cause threshold voltage shifts for a transistor of each of the one or more additional ones of the plurality of bit cells.

16. The computer readable medium as recited in claim 15, wherein the selected one of the plurality of bit cells and the one or more additional ones of the plurality of bit cells are determined based on each failing during a production test for at least a first operating point and passing a production test for at least a second operating point, and wherein the computer readable medium includes a data structure identifying the selected one of the plurality of bit cells and the one or more additional ones of the plurality of bit cells.

17. The computer readable medium as recited in claim 16, wherein the first operating point includes a first operating voltage and a first operating frequency, and wherein the second operating point includes a second operating voltage and a second operating frequency.

18. The computer readable medium as recited in claim 12, wherein testing the IC further comprises electrically isolating the selected one of the plurality of bit cells from one or more adjacent ones of the plurality of bit cells.

19. The computer readable medium as recited in claim 12, wherein testing the IC includes holding the gate terminal of a p-channel metal oxide semiconductor (PMOS) transistor at the predetermined state.

20. The computer readable medium as recited in claim 19, wherein testing the IC further comprises holding the gate terminal of the PMOS transistor at the predetermined state at a period sufficient to cause the threshold voltage to increase.

21. The computer readable medium as recited in claim 12, wherein testing the IC further comprises holding at least on additional internal node of the selected one of the plurality of bit cells at another predetermined state for a period sufficient to cause a shift in a threshold voltage of another transistor in the selected one of the plurality of bit cells.

22. A method comprising:
identifying selected ones of a plurality of bit cells of a memory implemented on an integrated circuit (IC), wherein the selected ones of the plurality of bit cells are identified based on having passed a test of the memory at a first operating point and having failed a test of the memory at a second operating point; and
performing a test of the IC, wherein performing the test includes applying test patterns to the memory while the IC is at a temperature greater than ambient temperature;
wherein said performing the test of the IC includes holding at least one internal node of a first of the selected ones of the plurality of bit cells at a predetermined state for a period sufficient to cause a change in a threshold voltage of a transistor in the first of the selected ones of the plurality of bit cells.

23. The method as recited in claim 22, further comprising:
holding an internal node of each of the selected ones of the plurality of bit cells to a predetermined state for a period sufficient to cause a change in a threshold voltage of a corresponding transistor in each of the selected ones of the plurality of bit cells.

24. The method as recited in claim 23, further comprising:
performing a production test subsequent to the dynamic burn-in test, wherein performing the production test includes determining if the selected ones of the plurality of cells pass during a test of the memory at the first operating point and the second operating point.

25. The method as recited in claim 24, wherein the first operating point comprises a first operating voltage and a first operating frequency, and wherein the second operating point comprises a second operating voltage and a second operating frequency.

26. The method as recited in claim 23, further comprising:
electrically isolating each of the selected ones of the plurality of bit cells during the dynamic burn-in test.

27. The method as recited in claim 22, wherein the transistor is a p-channel metal oxide semiconductor (PMOS) transistor.

28. The method as recited in claim 27, further comprising causing a threshold voltage of the PMOS transistor to become more negative.

29. The method as recited in claim 28, further comprising causing a threshold voltage of at least one additional PMOS transistor to become more negative in the first of the selected ones of the plurality of bit cells.
